(19) United States
(12) Patent Application Publication
(10) Pub. No.: US 2026/0181979 A1
(43) Pub. Date: Jun. 25, 2026

(54) METHOD FOR PRODUCING A HIGH-RESISTIVITY SEMICONDUCTOR STACK AND ASSOCIATED STACK

(71) Applicants: COMMISSARIAT A L'ENERGIE ATOMIQUE ET AUX ENERGIES ALTERNATIVES, PARIS (FR); SOITEC, BERNIN (FR)

(72) Inventors: Emmanuel AUGENDRE, GRENOBLE CEDEX 09 (FR); Christine LAURANT, GRENOBLE CEDEX 09 (FR); Shay REBOH, GRENOBLE CEDEX 09 (FR); Eric VANDERMOLEN, BERNIN (FR)

(21) Appl. No.: 19/124,134

(22) PCT Filed: Oct. 23, 2023
(86) PCT No.: PCT/EP2023/079435

§ 371 Date: Apr. 24, 2025

(30) Foreign Application Priority Data
Oct. 25, 2022 (FR) FR2211053

(51) Int. Cl. H10D 62/832

(52) U.S. Cl. CPC H10D 62/8325

(57) ABSTRACT

A method for producing a semiconductor stack including, from a first silicon layer, referred to as a support layer, forming a silicon carbide layer, extending over the support layer; and annealing the layers until cavities are formed, each cavity extending into the support layer, from the silicon carbide layer.

### TECHNICAL FIELD OF THE INVENTION

The technical field of the invention is that of semiconductor stacks to form silicon-on-insulator substrates, also called “SOI” substrates, and more particularly SOI substrates implemented in the radiofrequency field.

### TECHNOLOGICAL BACKGROUND OF THE INVENTION

High-resistivity semiconductor stacks, such as silicon-on-insulator, or SOI, substrates, are widely used for radiofrequency applications because they promote integrity of signals circulating in devices made on their surface.

An SOI substrate includes a first semiconducting layer, of silicon, called the “support layer” or “pedestal”, and a second semiconducting layer, of silicon, called the “active layer”. The active layer is to accommodate microelectronic components manufactured in or on the active layer. In this case, these are called “initial” or “front end” components, or even “FEOL” (Front End Of Line) components. The active layer is separated from the support layer by an insulating layer, for example of silicon oxide, disposed between the support layer and the active layer, and more particularly under the active layer. The insulating layer is then said to be “buried” or “BOX” for “Buried Oxide”. The insulating layer makes it possible to confine the predominant charge carriers in the active layer, which makes it possible to contemplate an operating frequency for front end components that is high, for example up to several tens of gigahertz.

However, charge carriers can accumulate in the support layer, in the vicinity of the insulating layer, creating a conductive sub-layer which severely impairs conduction in the active layer. There is therefore a need to reduce circulation of charge carriers in the support layer, in the vicinity of the insulating layer.

Article [“RF Performance of a Commercial SOI Technology Transferred Onto a Passivated HR Silicon Substrate”, Dimitri Lederer and Jean-Pierre Raskin, IEEE TRANSACTIONS ON ELECTRON DEVICES, VOL. 55, NO. 7, July 2008] brings a solution to this problem by forming a trapping layer, disposed between the support layer and the insulating layer, whose role is to trap charge carriers. The trapping layer comprises polycrystalline silicon. Trapping charge carriers is then performed at the grain boundaries, where the silicon dangling bonds are located. The trapping layer is deposited by Low Pressure Chemical Vapour Deposition (LPCVD), followed by rapid annealing at a temperature of 1000° C., so as to form the silicon grains.

The effectiveness of the trapping layer relies on the density of silicon dangling bonds and therefore on the density of grain boundaries. However, heat treatments implemented during the manufacture of microelectronic components at the active layer tend to reduce the number of grains and therefore to reduce the number of grain boundaries. The polycrystalline silicon trapping layer therefore requires a restricted thermal budget.

Another approach to trapping charge carriers consists in forming bubbles in the support layer, in the vicinity of the interface between the support layer and the insulating layer. Dangling bonds at the free surface of each bubble thereby enable charge carriers to be trapped. The article [“Chemical and electrical properties of cavities in silicon and germanium”, S. M. Myers, D. M. Follstaedt, G. A. Petersen, C. H. Seager, H. J. Stein & W. R. Wampler, Nuclear instruments and Methods in Physics Research B 106 (1995) 379-385] describes a method for forming bubbles in a silicon layer by helium ion implantation. However, bubbles formed are about 200 nm away from the interface between the support layer and the insulating layer. In addition, the maximum density of bubbles is located at a distance from the interface of between 1000 nm and 1500 nm. The trapping capacity at the interface is therefore limited. In addition, modulating the implantation energy to bring the bubbles closer to the interface could cause exfoliation of the insulating layer. Furthermore, the implantation time can be long (in the order of 20 min to implant ions into a 300 mm diameter substrate, under an implantation current of 10 mA and a dose of 10¹⁷ cm⁻²).

Another known solution is described in document FR3091011 A1 which discloses an SOI substrate comprising a polycrystalline silicon carbide layer extending at the surface of the support layer. The carbide layer is preferably polycrystalline and thus enables charge carriers to be trapped, in the same way as a polycrystalline silicon trapping layer. Growing the carbide layer is carried out by growing from the support layer by means of a carbon precursor or by CVD. However, the thickness of the carbide layer disclosed is limited to 5 nm. But, with a low thickness, the carbide layer is chemically fragile and may be contaminated by species brought during complementary manufacturing steps (such as the manufacture of the insulating layer and/or the active layer) and which have migrated to the carbide layer.

There is therefore a need to provide a semiconductor stack for effectively trapping charge carriers in the support layer, which is also robust in relation to complementary manufacturing steps (such as the manufacture of the insulating layer, the active layer or even the front end components).

### SUMMARY OF THE INVENTION

The invention relates to a method for manufacturing a semiconductor stack comprising, from a first silicon layer, called the support layer:
forming a silicon carbide layer, extending over the support layer, having a thickness, measured from the support layer, greater than 5 nm, a fraction of carbon atoms of the silicon carbide layer, within 20 nm of the support layer, being strictly greater than 50%; and
annealing the support layer and the silicon carbide layer until cavities are formed, each cavity extending into the support layer from the silicon carbide layer, a concentration of oxygen in contact with the silicon carbide layer during the annealing step being less than 10 ppm, preferably less than 5 ppm, or even zero.

During annealing, silicon atoms in the support layer migrate towards the carbide layer, thus forming cavities, that is, hollow zones located in the support layer, from the carbide layer.

Cavities formed in the support layer provide silicon dangling bonds and thus enable charge carriers to be trapped in the support layer. The arrangement of the cavities enables the charge carriers to be effectively trapped as close as possible to the interface between the support layer and the carbide layer.

In addition, silicon carbide is a semiconductor having an indirect band gap with a difference greater than 2 eV, or even 3 eV. The carbide layer thus prevents circulation of charge carriers in the vicinity of the insulating layer.

Since trapping does not rely on the presence of grain boundaries, which are sensitive to temperature, the stack then has improved morphological stability. In addition, during a heat treatment, the temperature involving coalescence of the cavities is significantly higher than the temperature involving coalescence of the grains in a polycrystalline structure. Besides, the temperature involving coalescence of the cavities is higher than the temperatures implemented during complementary manufacturing steps. In addition, while coalescence of the grains is accompanied with the disappearance of traps, the possible coalescence of the cavities is performed at a constant surface area.

As the silicon carbide layer is richer in carbon, it makes it possible to activate the migration of silicon atoms from the support layer during annealing and effectively form the cavities.

The thickness of the silicon carbide layer greater than 5 nm improves its robustness, especially chemically, in relation to complementary manufacturing steps (such as the manufacture of “front end” components). Indeed, it is less affected by contaminants that may migrate.

The silicon carbide layer can undergo pitting oxidation when annealed in an environment comprising oxygen. Pitting damages the silicon carbide layer and can slow down migration of silicon atoms and therefore formation of the cavities. Annealing in a low-oxygen atmosphere limits the occurrence of pitting and therefore improves reproducibility of the method.

Finally, the method does not rely on ion implantation to form the cavities, simplifying its implementation.

Annealing can be carried out for a duration of between 15 minutes and 2 hours at a temperature of between 900° C. and 1100° C.

The silicon carbide layer resulting from the formation step is advantageously amorphous and annealing the layers is advantageously carried out so as to crystallise the silicon carbide layer in a polycrystalline arrangement.

The support layer is advantageously oriented in a plane.

A fraction of carbon atoms of the silicon carbide layer, within 20 nm of the support layer, measured perpendicularly to the plane, is advantageously less than or equal to 70%.

The thickness of the silicon carbide layer is preferably less than 500 nm.

Each cavity may have facets, each facet being preferably oriented in parallel to a crystallographic plane forming, for example, part of the family of {111} crystallographic planes or part of the family of {113} crystallographic planes.

The cavities extend over a distance, measured perpendicularly to the plane and from the silicon carbide layer, preferably of between 5 nm and 100 nm.

The method preferably comprises forming an insulating layer extending over the silicon carbide layer. Advantageously, the insulating layer is to form a “buried” layer, referred to as “BOX” for “Buried Oxide”.

According to a first mode of implementation, forming the insulating layer is carried out by deposition, before said annealing.

Annealing the support layer, the silicon carbide layer and the insulating layer can be carried out under an atmosphere comprising an oxygen concentration of less than 1%.

According to a second mode of implementation, forming the insulating layer is carried out by transfer from a donor substrate, after annealing the layers.

In common with the two aforementioned modes of implementation, the method can comprise forming a second crystalline layer, extending over the insulating layer. The insulating layer then forms a “BOX” layer.

Another aspect of the invention relates to a semiconductor stack comprising:
a first silicon layer, referred to as the support layer;
a silicon carbide layer, extending over the support layer, having a thickness, measured from the support layer, greater than 5 nm; and
cavities, each cavity extending into the support layer from the silicon carbide layer.

The silicon carbide layer is advantageously polycrystalline.

Advantageously, the support layer is oriented in a plane and the cavities extend over a distance, measured perpendicularly to the plane and from the silicon carbide layer, of between 5 nm and 100 nm.

Advantageously, when the cavities extend over a distance, measured perpendicularly to the plane and from the silicon carbide layer, greater than 15 nm, then each cavity has facets, each facet being oriented in parallel to a crystallographic plane.

Advantageously, each cavity has a pyramidal shape and has a base aligned with the interface between the support layer and the silicon carbide layer.

Advantageously, the apex of the pyramid extends into the support layer.

Advantageously, the cavities are only located at the interface between the support layer and the silicon carbide layer. Stated differently, each cavity extends only into the support layer from the silicon carbide layer.

Advantageously, the silicon carbide layer is non-porous.

Advantageously, each cavity has a free surface surrounding an internal volume, at least one portion of the free surface separating said internal volume from the support layer and at least one other portion of the free surface separating the internal volume from the silicon carbide layer.

Advantageously, each portion of the free surface separating the internal volume of the cavity from the support layer comprises silicon atoms, at least some of which have a dangling bond.

The invention and its different applications will be better understood upon reading the following description and examining the accompanying figures.

### BRIEF DESCRIPTION OF THE FIGURES

The figures are set forth by way of indicating and in no way limiting purposes of the invention. Unless otherwise specified, a same element appearing in different figures has a single reference.

FIG. 1 schematically represents a first embodiment of a semiconductor stack according to the invention.

FIG. 2 schematically represents a first mode of implementation of a manufacturing method according to the invention.

FIG. 3a schematically represents a first example of a first step of the manufacturing method according to the invention.

FIG. 3b schematically represents a second example of the first step of the manufacturing method according to the invention.

FIG. 4 schematically represents a second step of the manufacturing method according to the invention.

FIG. 5 schematically represents a third step of the manufacturing method according to the invention.

FIG. 6 schematically represents a fourth step of the manufacturing method according to the invention.

FIG. 7 schematically represents a second first mode of implementation of a manufacturing method according to the invention.

FIG. 8 schematically represents a fifth step of the manufacturing method according to the invention.

FIG. 9 represents an image obtained by transmission microscopy of a semiconductor stack manufactured by the manufacturing method according to the invention.

### DETAILED DESCRIPTION

The invention offers to improve semiconductor stacks intended to form an SOI substrate and especially a substrate for radiofrequency applications.

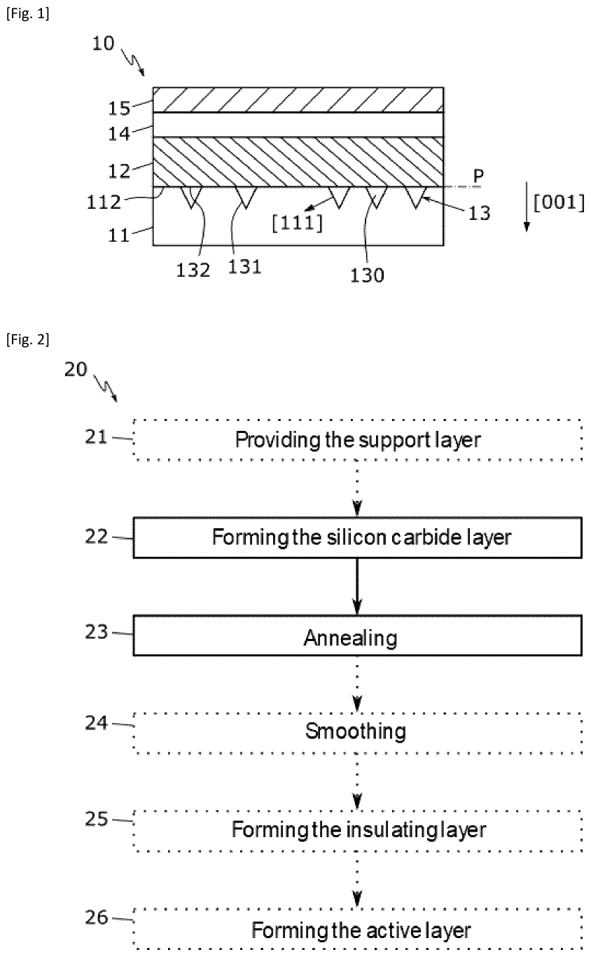

FIG. 1 schematically represents a first embodiment of a semiconductor stack 10 according to the invention. The stack 10 comprises:
a first silicon layer 11, referred to as a support layer;
a silicon carbide layer 12; and
cavities 13.

The support layer 11 extends, for example, in a given plane P. This is, for example, the plane of a silicon wafer from which an SOI substrate will be formed. Advantageously, the support layer 11 is a resistive support, that is, having a resistivity greater than 1 kΩ·cm.

The silicon carbide layer 12 (also called the SiC layer) extends over the support layer 11 in the given plane P. The SiC layer 12 is in direct contact with the support layer 11, forming an interface 112 between the two layers.

The stack 10 is remarkable in that it comprises a plurality of cavities 13 extending into the support layer 11. Each cavity 13 is hollow, that is, devoid of any solid or liquid material. They may comprise a species in gaseous form having a low partial pressure. However, they are preferably completely empty. Each cavity 13 extends into the support layer 11, from the SiC layer 12. That is, each cavity 13 extends into the support layer 11 from the interface 112. Each cavity 13 then has a free surface 131, 132 surrounding an internal volume 130 of the cavity 13. At least one portion 131 of the free surface separates said internal volume 130 from the support layer 11 and at least one other portion 132 of the free surface separates the internal volume 130 of the cavity from the SiC layer 12.

The portion or portions 131 of the free surface separating the internal volume 130 of the cavity from the support layer 11 are formed of silicon atoms, at least some of which have a dangling bond. By dangling bond, it is meant an atomic orbital not involved in a chemical bond with other elements. Dangling bonds make it possible trap charge carriers circulating in the support layer 11 and in the vicinity of the SiC layer 12.

The dangling bonds and cavities also make it possible to trap impurities, such as hydrogen ions or atoms, helium atoms or metals such as lithium or copper, which have migrated into the support layer 11 during additional manufacturing steps, for example (such as the manufacture of “front end” components). The resistivity of the support layer 11 is therefore not degraded during additional manufacturing steps.

The thermodynamic stability and diffusion formation of the cavities 13 tend to promote faceting of the cavities. Portions 131 of the free surface 131, 132 of each cavity 13 are then preferably aligned along crystallographic planes of the support layer 11. For example, when the support layer 11 has a (001) plane, at the interface 112 with the SiC layer 12 (that is, the (001) plane and the plane P coincide), the cavities 13 may be facetted by having portions parallel to crystallographic planes of the family of {111} planes (that is, the (111), (−111), (1-11) and (−1-11) planes) or of the family of {113} planes (that is, the (113), (−113), (1-13) and (−1-13) planes). The cavities 13 may then have an inverted pyramid shape, with a square or triangular base, said base of which coincides with the interface between the support layer 11 and the SiC layer 12. However, faceting does not necessarily depend on the plane at the interface 112 of the support layer 11 with the SiC layer 12. Other families of crystallographic planes are contemplatable.

In order to determine orientation of the crystallographic planes, it is advantageous to consider cavities 13 extending over a distance 133, measured perpendicularly to the plane P, greater than 15 nm. Indeed, it may be difficult to distinguish the families of planes {113} below this distance.

FIG. 1 represents the [111] and [001] directions, normal to the (001) and (111) crystallographic planes, by arrows.

Each cavity 13 preferably extends from the SiC layer 12 over a distance 133 of between 5 nm and 100 nm. Said distance 133 is measured perpendicularly to the plane P in which the SiC layer 12 extends, that is, along [001] in the present example. Said distance 133 is measured from the carbide layer 12, that is, from the interface 112 separating the support layer 11 and the carbide layer 12.

In the example of [FIG. 1], the stack 10 also comprises an insulating layer 14 and an active layer 15. In this way, the stack 10 forms an SOI substrate. The insulating layer 14 extends over the SiC layer 12. Advantageously, it has a thickness of between 100 nm and 1000 nm. For example, it comprises an oxide, such as silicon oxide SiO₂. The active layer 15 comprises a crystalline or polycrystalline semiconductor and extends over the insulating layer 14. The insulating layer 14 thus separates the SiC layer 12 and the active layer 15. It is said to be “buried” under the active layer 15. The active layer 15 advantageously has a thickness of between 50 nm and 500 nm and comprises, for example, crystalline silicon or polycrystalline silicon or another crystalline semiconductor material used in the radiofrequency field, such as indium phosphide or gallium nitride.

The SiC layer 12 is advantageously polycrystalline. Thus, it contributes to the trapping of charge carriers, in the same way as a polycrystalline silicon trapping layer, as described in prior art. The charge carriers are trapped by the dangling bonds located at the grain boundaries of the polycrystalline arrangement.

FIG. 2 schematically represents a manufacturing method according to the invention, for manufacturing the stack 10.

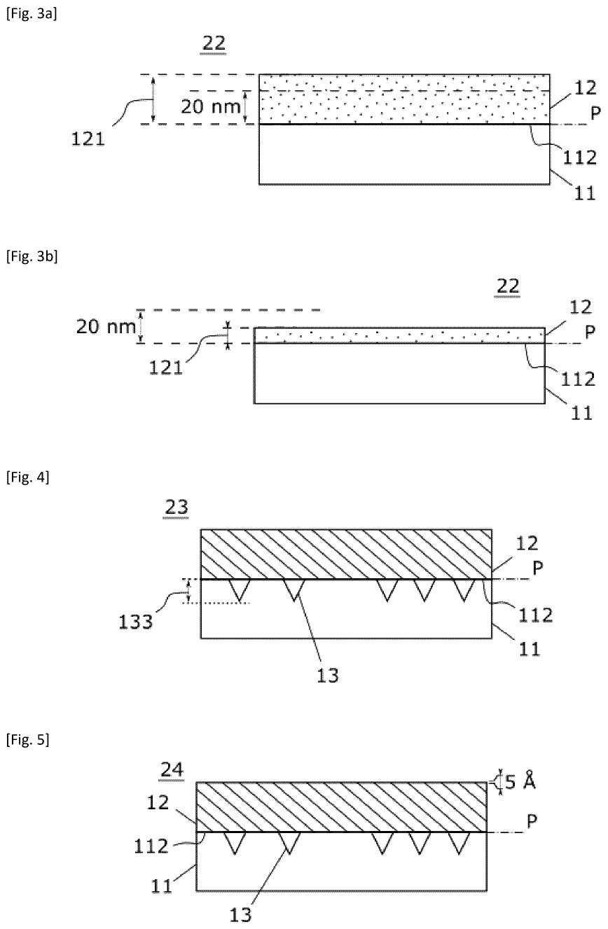

The manufacturing method 20 comprises, from a support layer 11, a step of forming 22 a silicon carbide layer 12 (referred to as a SiC layer), extending over the support layer 11. Two examples of the silicon carbide layer 12 obtained are illustrated in [FIG. 3a] and [FIG. 3b].

The SiC layer 12 is formed, for example, by Chemical Vapour Deposition (CVD) from the support layer 11. For example, it is a Plasma Enhanced CVD Deposition (PECVD). The SiC layer 12 is obtained, for example, by PECVD deposition of a carbon precursor, such as tetramethylsilane Si(CH₃)₄, also called “TMS”. The SiC layer 12 produced then extends over the support layer 11.

The support layer 11 extends in a plane P. It preferably has a (001) crystallographic plane in the plane P. The SiC layer 12 has a thickness 121, measured from the support layer 11 and perpendicularly to the plane P, greater than 5 nm and advantageously less than 500 nm.

The method 20 further comprises a step of annealing 23 the support layer 11 and the SiC layer 12 until cavities 13 extending into the support layer 11 are formed, as illustrated in [FIG. 4]. Each cavity 13 then extends into the support layer 11 from the SiC layer 12. During annealing 23, the temperature increases mobility of the silicon atoms in the support layer 11 and some of these atoms, especially those close to the SiC layer 12. The difference in fractions of silicon atoms between the support layer 11 and the SiC layer 12 tends to orient migration of the silicon atoms from the support layer 11 towards the SiC layer 12, thus digging several cavities 13 in the support layer 11. Forming each cavity 13 then has its starting point at the interface between the support layer 11 and the SiC layer 12. Each cavity 13 then extends into the support layer 11 along a direction substantially perpendicular to the plane P. By substantially perpendicular, it is meant perpendicular to within 20°. Annealing 23 the support layer 11 and the SiC layer 12 is preferably simultaneous.

Since forming each cavity 13 has its starting point at the interface between the support layer 11 and the SiC layer 12, the method only forms cavities extending from the interface between the support layer 11 and the SiC layer 12. Stated differently, the method does not allow cavities distant from said interface between the support layer 11 and the SiC layer 12 to be formed (these cavities distant from the interface may be called pores or bubbles).

When the support layer 11 comprises defects such as amorphous zones or grain boundaries, these defects can assist or facilitate migration of silicon atoms towards the SiC layer 12.

The annealing temperature 23 enabling cavities 13 to be formed is advantageously between 900° C. and 1100° C. Below 900° C., the mobility of silicon atoms is not sufficient to form cavities 13 for a duration that is compatible with an industrial throughput. Above 1100° C., the mobility of silicon atoms is such that it allows the migration of atoms between cavities 13, tending to form cavities that are few in number but very large in size (that is, extending beyond 100 nm from the SiC layer 12). Trapping of charge carriers is improved when the density of cavities 13 (that is, the number of cavities 13 per unit area of the interface 112) increases. On the other hand, trapping deteriorates when the density of cavities 13 decreases.

The SiC layer 12 is advantageously formed at a temperature of between 300° C. and 500° C. In this way, before annealing 23, it has an amorphous phase. Annealing 23 the layers, and especially the SiC layer 12, between 900° C. and 1100° C. has the effect of crystallising the SiC layer 12 in a polycrystalline arrangement. This crystallisation has two beneficial effects. Firstly, the grain boundaries of the polycrystalline arrangement contribute to the trapping of charge carriers, enhancing the trapping carried out by the cavities 13. Secondly, crystallisation also accelerates the migration of silicon atoms from the support layer 11 to the SiC layer 12, in the same way as pumping of silicon atoms, having the effect of accelerating the formation kinetics of the cavities 13.

Both before and after annealing, the SiC layer 12 is non-porous. For example, when the SiC layer 12 is polycrystalline (for example after annealing), the non-porosity is provided by the grain boundaries of the SiC layer 12.

Annealing 23 is advantageously carried for a duration of between 15 min and 2 h, so that the migration of silicon atoms from the support layer 11 makes it possible to obtain cavities 13 extending at least 5 nm from the SiC layer 12 and at most 100 nm from this layer. The dimension of the cavities 13 (measured perpendicularly to the plane P and from the SiC layer 12) is proportional to the duration of annealing 23. An annealing duration in the order of 15 minutes is compatible with an industrial throughput. An annealing duration in the order of 2 h makes it possible to form cavities 13 of large size, close to 100 nm, extending the trapping coverage of the charge carriers in the support layer 11. The annealing duration in the order of 2 h is also compatible with an industrial throughput. Indeed, annealing can be carried out in a furnace, enabling several plates, for example several tens, to be treated simultaneously. In contrast, ion implantation as implemented in prior art carries out a plate-by-plate treatment.

The migration of silicon atoms, and therefore the formation kinetics of the cavities 13, is accelerated when the SiC layer 12 has a fraction of carbon atoms (also called the carbon fraction) which, before annealing 23, is at least equal to the fraction of silicon atoms. The SiC layer 12 thus has, before annealing 23, a carbon fraction greater than 50% and advantageously less than 70%. The silicon fraction in the SiC layer 12 is thus, before annealing 23, less than 50.

The formation kinetics of the cavities 13 is particularly accelerated when the difference in fractions between the carbon and silicon atoms is large in the vicinity of the interface 112 between said SiC layer 12 and the support layer 11. On the other hand, the carbon fraction in the SiC layer 12 beyond 20 nm from the support layer 11 has no significant impact on the formation kinetics of the cavities 13. So, when the SiC layer 12 has a thickness 121 greater than 20 nm (measured perpendicularly to the plane P and from the interface 112 with the support layer 11), as illustrated by [FIG. 3a], it then has a part, extending over at least 20 nm from the support layer 11 and in which the carbon fraction is greater than 50% and advantageously less than or equal to 70%. When the SiC layer 12 has a thickness 121 less than or equal to 20 nm, as illustrated by [FIG. 3b], it then has, over its entire thickness 121, a carbon fraction greater than 50% and advantageously less than or equal to 70%. In other words, the carbon fraction of the SiC layer 12, within 20 nm of the support layer 11 (measured perpendicularly to the plane P and from the interface 112), is advantageously between 50% and 70%.

The SiC layer 12 reacts with oxygen and can oxidise, for example by pitting. Annealing 23 is therefore carried out by minimising oxygen contact with the SiC layer 12. Annealing 23 of the stack 10 is carried out by maintaining a concentration of oxygen in contact with the SiC layer 12 that is less than 10 ppm, preferably less than 5 ppm, or even zero.

Annealing 23 is for example carried out in a neutral atmosphere, comprising for example at least one neutral gas such as nitrogen or argon. The neutral atmosphere is then dimensioned so that it has an oxygen concentration of less than 10 ppm or even less, at least for the duration of annealing 23.

The method 20, according to the implementation of [FIG. 2], may also include a step of forming 25 an insulating layer 14 and a step of forming 26 a semiconducting active layer 15 so that the final stack 10 forms an SOI substrate, as illustrated by [FIG. 1].

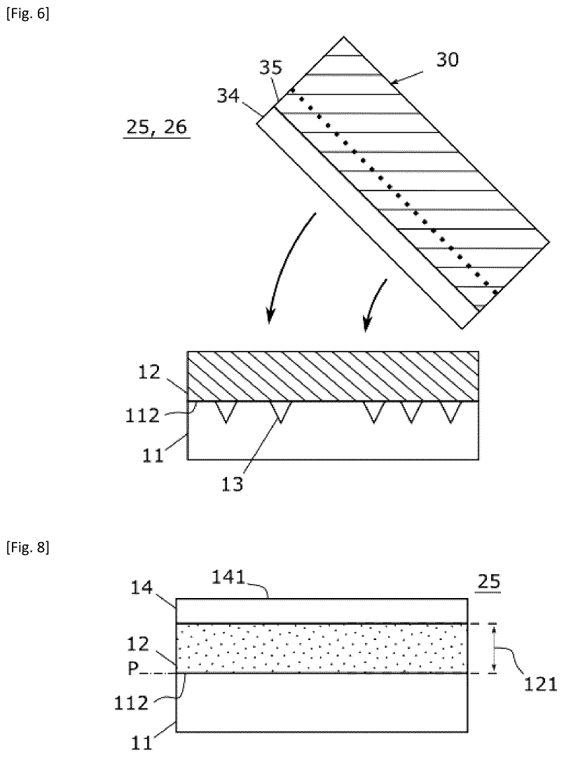

Forming 25 the insulating layer 14, illustrated in [FIG. 6], is advantageously carried out by transfer from a donor substrate 30. The principle of transfer from a donor substrate 30 is known as SmartCut™. When forming 25 the insulating layer 14 is carried out by transfer, forming 26 the active layer 15 is advantageously also carried out by transfer from a donor substrate and if possible from the same donor substrate 30. Advantageously, forming 25, 26 the two aforementioned layers is carried out simultaneously.

Before forming 25 the insulating layer 14 is carried out, it may be necessary to prepare a surface 122 of the SiC layer 12, which is to accommodate the insulating layer 14. In this case, the method 20 comprises, before forming 25 the insulating layer 14, a step of smoothing 24 said surface 122. Smoothing 24, illustrated in [FIG. 5], can be carried out by Chemical Mechanical Polishing (CMP). Smoothing 24 is carried out so that the SiC layer 12 has a surface roughness of less than or equal to 5 Å. Surface roughness is also called mean roughness or RMS (Root Mean Square) roughness. The roughness of the surface 122 of the SiC layer can be evaluated by means of an Atomic Force Microscope (AFM). The roughness can be evaluated on a portion of the surface 122 area of about 1 μm².

Simultaneously forming 25, 26 the insulating and active layers 14, 15 by transfer can be carried out from a same donor substrate 30, the latter then comprising a semiconducting layer 35, for example of crystalline or polycrystalline silicon or crystalline indium phosphide or crystalline gallium nitride, on which an insulating layer 34, for example of silicon oxide, extends. For example, the insulating layer 34 has a thickness of between 100 nm and 1000 nm. For example, the underlying semiconducting layer 35 has a thickness greater than 50 nm, or even greater than 500 nm.

The simultaneous formation operations 25, 26 may then include a sub-step of implanting light ions (for example hydrogen or helium ions) into the semiconducting layer 35 of the donor substrate 30 to a depth of between 50 nm and 500 nm below the insulating layer 34. Implantation is carried out, for example, at a dose of a few 10¹⁶/cm² and at an energy of a few tens of keV.

The simultaneous formation operations 25, 26 then comprise a sub-step of cleaning the free surface 341 of the insulating layer 34 of the donor substrate 30, in order to allow direct bonding between said insulating layer 34 of said donor substrate 30 and the SiC layer 12 of the stack 10. Cleaning the free surface 341 of the insulating layer 34 advantageously uses recipes known from silicon technologies, such as the so-called “RCA” (Radio Corporation of America) recipe or even a so-called CARO recipe, comprising a mixture of hydrogen peroxide and sulphuric acid.

It is advantageous, however, to allow good adhesion of the insulating layer 34 to the SiC layer 12, that cleaning is also followed by an activation of the free surface 341 of the insulating layer 34 of the donor substrate 34. For example, said activation is carried out by means of a plasma, for example of oxygen or nitrogen.

Simultaneously forming 25, 26 the insulating and active layers 14, 15 by transfer comprises a sub-step of bonding the donor substrate 30 to the stack 10, as illustrated by [FIG. 6], the free layer 341 of the insulating layer 34 of the donor substrate 34 being pressed against the SiC layer 12 of the stack 10. Bonding is then followed by a so-called “separation annealing”, aimed at separating the semiconducting layer 35 of the donor substrate 30 into two parts, in a plane including the light ions previously implanted. After separation annealing, the stack 10 thus comprises an insulating layer 14, as illustrated in [FIG. 1], extending over the SiC layer 12 (because it is bonded to the latter). The semiconducting layer 35 forms the active layer 15 of the stack 10.

Planarising of the active layer 15 and/or complementary annealing of the stack 10 can be carried out to prepare the active layer 15 and/or improve the adhesion of the layers of the stack 10.

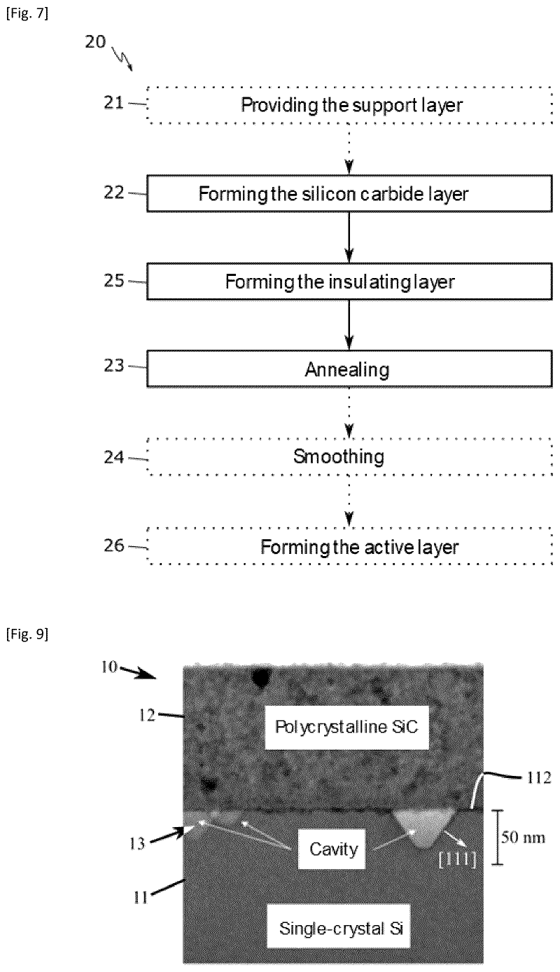

FIG. 7 represents schematically a second implementation of the method 20. According to this implementation, the step of forming 25 the insulating layer 14 takes place before the step of annealing 23 the stack 10. This inversion of the steps simplifies the annealing step 23 in that the neutral atmosphere, previously described, no longer needs to have an oxygen concentration of less than 10 ppm. It can be less than 1% only. The manufacturing method 20 is therefore simpler to implement, especially with industrial equipment.

According to this implementation, the insulating layer 14 is formed on the SiC layer 12, as illustrated by [FIG. 8]. It forms a barrier for reducing or even stopping the diffusion of species coming from the surrounding atmosphere towards the SiC layer 12. The stack 10 can then simply be annealed 23 in a neutral atmosphere having an oxygen concentration of less than 1%.

Forming 25 the insulating layer 14 before annealing is preferably carried out by CVD deposition, for example of a tetraethyl orthosilicate Si(OCH₂CH₃)₄ (also called “TEOS”) precursor. CVD deposition is advantageously Plasma-Enhanced (referred to as PECVD) to produce a layer of silicon dioxide SiO₂ from the precursor. This deposition can be carried out at a temperature of between 300° C. and 500° C., so as not to anticipate annealing 23 of the stack 10. The deposition is carried out so as to form an insulating layer 14 having a thickness 121, measured perpendicularly to the plane P, of between 100 nm and 1000 nm.

Forming 25 the insulating layer 14 is advantageously carried out in the same equipment as that used to form the SiC layer 12. This prevents water vapour from the outside atmosphere (for example from the clean room) from being deposited onto the SiC layer 12 (at the risk of oxidising the latter).

The method 20 may also comprise, in order to manufacture a stack 10 of the SOI substrate type, forming 26 the active layer 15. Unlike the implementation of [FIG. 2], the method 20 according to [FIG. 7] only forms the active layer 15 after annealing 23. The active layer 15 can be formed by transfer from a donor substrate 30 as illustrated in [FIG. 6]. However, the donor substrate 30 herein only includes the crystalline or polycrystalline semiconducting layer 35. Forming 25 the insulating layer 14 before annealing 23 thus makes it possible to simplify the step 26 of forming the active layer 15 by transfer, in that only a single layer is transferred.

Forming 26 the active layer 15 by transfer preferably comprises a light ion implantation, as described previously. However, the depth of implantation is adjusted in order to transfer, onto the stack 10, an active layer 15 having a thickness of between 50 nm and 500 nm. Bonding the donor substrate 30 is also preferably prepared as described previously. The free surface of the donor substrate 30 is especially also activated by means of an oxygen or nitrogen plasma in order to improve bonding.

The insulating layer 14 of the stack 10 may also comprise, before forming 26 the active layer 15, smoothing 24 a surface 141 of the insulating layer for receiving the active layer 15. Smoothing 24 is advantageously similar to smoothing described with reference to [FIG. 5].

The method 20 may also comprise, in a manner common to the embodiments of [FIG. 2] and [FIG. 7], a step 21 of providing the support layer 11, prior to the step of forming the SiC layer 12. Further to supplying the support layer 11, the provide step 21 may comprise preparing the support layer 11 so as to allow, or even promote, during annealing 23, diffusion of silicon atoms from the support layer 11 towards the SiC layer 12. The preparation may comprise the removal of organic or metallic contaminants, dopants or particles. The removal may be performed by implementing known recipes such as a so-called “CARO” wet recipe (aimed at removing organic contaminants) or sequences of the “RCA” recipe, comprising for example a so-called “HF” cleaning (aimed at removing dopants), a so-called “SC1” cleaning (aimed at removing organic contaminants and particles) and/or a so-called “SC2” cleaning (aimed at removing metallic contaminants). When the support layer 11 comprises a native oxide, it is then advantageous to remove it by means of a plasma, for example, preferably in the chamber which will accommodate forming 22 the SiC layer 12, or even annealing 23 the stack 10.

FIG. 9 shows a bright-field image obtained by Transmission Electron Microscopy (referred to as “TEM”) of a semiconductor stack 10 according to the invention. This stack has been obtained by means of the method according to the present invention. The stack 10 comprises a single-crystal silicon support layer 11, a polycrystalline SiC layer 12 and a plurality of cavities 13 extending into the support layer 11 from the interface 112 between the support layer 11 and the SiC layer 12. The support layer 11 has a [001] plane at the interface 112 with the SiC layer 12 so that the cavities have facets extending along {111} crystallographic planes (represented by an arrow oriented along the [111] direction, normal to the (111) planes).

The different orientations of the SiC grains in the SiC layer 12 result in a large difference in contrast within this layer. This difference in contrast should not, however, be construed as the presence of pores, bubbles or vacancies. In the particular case of [FIG. 9], the SiC layer also has different crystalline structures, for example a majority of crystallised grains in the 3C polytype and a minority of grains in other polytypes including 4H and 6H. This difference in structure also contributes to the appearance of the SiC layer 12 observed in [FIG. 9]. The SiC layer 12 is non-porous. The support layer 11 is also non-porous.

In this image, the height of the cavities 13 is between 10 nm and 40 nm. This height is measured perpendicularly to the plane P and from the SiC layer 12.

Each cavity 13 has a pyramidal shape and has a base aligned with the interface between the support layer 11 and the SiC layer 12. Stated differently, the base of the pyramid is coincident with this interface. The apex of the pyramid is located in the support layer 11, at variable depths depending on the size of the cavities 13.

As can be noticed in [FIG. 9], the cavities 13 are located only at the interface between the support layer 11 and the SiC layer 12.

1. A method for manufacturing a semiconductor stack, comprising, from a first silicon layer, forming a support layer:
forming a silicon carbide layer, extending over the support layer, having a thickness, measured from the support layer, greater than 5 nm, a fraction of carbon atoms of the silicon carbide layer, within 20 nm of the support layer, being strictly greater than 50%; and
annealing the support layer and the silicon carbide layer until cavities are formed, each cavity extending into the support layer from the silicon carbide layer, a concentration of oxygen in contact with the silicon carbide layer, during the annealing step, being less than 10 ppm.

2. The method according to claim 1, wherein annealing is carried out for a duration of between 15 min and 2 h at a temperature of between 900° C. and 1100° C.

3. The method according to claim 1, wherein the silicon carbide layer resulting from the formation step is amorphous, annealing the layers being carried out so as to crystallise the silicon carbide layer in a polycrystalline arrangement.

4. The method according to claim 1, wherein the support layer is oriented in a plane and wherein a fraction of carbon atoms of the silicon carbide layer, within 20 nm of the support layer, is less than or equal to 70%.

5. The method according to claim 1, wherein the thickness of the silicon carbide layer is less than 500 nm.

6. The method according to claim 1, wherein the support layer is oriented in a plane and wherein the cavities extend over a distance, measured perpendicularly to the plane and from the silicon carbide layer, of between 5 nm and 100 nm.

7. The method according to claim 1, comprising forming an insulating layer extending over the silicon carbide layer.

8. The method according to claim 7, wherein forming the insulating layer is carried out by deposition, before said annealing.

9. The method according to claim 1, wherein annealing the support layer, the silicon carbide layer and the insulating layer is carried out in an atmosphere comprising an oxygen concentration of less than 1%.

10. A semiconductor stack comprising:
a first silicon layer, referred to as a support layer;
a silicon carbide layer, extending over the support layer, having a thickness, measured from the support layer, greater than 5 nm; and
cavities, each cavity extending into the support layer from the silicon carbide layer.

11. The semiconductor stack according to claim 10, wherein the support layer is oriented in a plane and wherein the cavities extend over a distance, measured perpendicularly to the plane and from the silicon carbide layer, of between 5 nm and 100 nm.

12. The semiconductor stack according to claim 11, wherein when the cavities extend over a distance, measured perpendicularly to the plane and from the silicon carbide layer, greater than 15 nm, then each cavity has facets, each facet being oriented in parallel to a crystallographic plane.

13. The semiconductor stack according to claim 10, wherein each cavity has a pyramidal shape and has a base aligned with the interface between the support layer and the silicon carbide layer.

14. The semiconductor stack according to claim 10, wherein the cavities are located only at the interface between the support layer and the silicon carbide layer.

15. The semiconductor stack according to claim 10, wherein the silicon carbide layer is non-porous.
